(19) United States
(12) Patent Application Publication
(10) Pub. No.: US 2007/0273001 A1
(43) Pub. Date: Nov. 29, 2007

(54) SYSTEM ON CHIP AND METHOD FOR MANUFACTURING THE SAME

(76) Inventors: Jung-Ching Chen, Taichung County (TW); Ming-Tsung Tung, Hsinchu, (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,901

(22) Filed: May 24, 2006

(51) Int. Cl. H01L 29/00

(52) U.S. Cl. 257/500

(57) ABSTRACT

A system-on-chip semiconductor structure. The system-on-chip semiconductor structure comprises a substrate, a low voltage device, a middle voltage device, at least one high voltage device and a plurality of isolation structures. The substrate has a low voltage circuit region and a high voltage circuit region. The low voltage device is located on the low voltage circuit region of the substrate. The middle voltage device is located on the low voltage circuit region of the substrate. The high voltage device is located on the high voltage circuit region of the substrate. The isolation structures are located in the substrate for isolating the low voltage device, the middle voltage device and the high voltage device from each other.

### BACKGROUND OF THE INVENTION

1. Field of Invention

The present invention relates to a semiconductor structure and a method for manufacturing the same. More particularly, the present invention relates to a semiconductor structure having high voltage devices, a low voltage device and a middle voltage device arranged on the same chip and a method for manufacturing the same.

2. Description of Related Art

With the development of the new semiconductor manufacturing technology, the system-on-chip which is a single chip possesses many functions attracts a great attention. The driver of the thin film transistor (TFT) crystal display or color supper twisted nematic (CSTN) crystal display generally possesses three kinds of integrated circuits including a signal processor, a gate driver and a source driver. Furthermore, these integrated circuits are located in different chips.

With the decreasing of the product size, the size of the chip is decreased to meet the product specification. Generally, the low voltage device and the middle voltage device are arranged on the same chip. Meanwhile, the high voltage device is located on another chip to decrease the number of the chips in the product so that the low voltage device and the middle voltage device can be prevented from being affected by the intensive electric field generated while the high voltage device is operated.

However, with the enhancing of the power of the product, the number of the chips in the product is increased. Therefore, how to decrease the number of the chips in the product without affecting the functionality of the product becomes the main study task nowadays.

### SUMMARY OF THE INVENTION

Accordingly, at least one objective of the present invention is to provide a system-on-chip semiconductor structure capable of decreasing the size of the semiconductor device.

At least another objective of the present invention is to provide a system-on-chip semiconductor structure capable of arranging high voltage devices, a middle voltage device and a low voltage device at the same chip.

At least the other objective of the present invention is to provide a method for manufacturing a system-on-chip semiconductor structure capable of forming high voltage devices, a middle voltage device and a low voltage device at the same chip.

To achieve these and other advantages and in accordance with the purpose of the invention, as embodied and broadly described herein, the invention provides a system-on-chip semiconductor structure. The system-on-chip semiconductor structure comprises a substrate, a low voltage device, a middle voltage device, at least one high voltage device and a plurality of isolation structures. The substrate has a low voltage circuit region and a high voltage circuit region. The low voltage device is located on the low voltage circuit region of the substrate. The middle voltage device is located on the low voltage circuit region of the substrate. The high voltage device is located on the high voltage circuit region of the substrate. The isolation structures are located in the substrate for isolating the low voltage device, the middle voltage device and the high voltage device from each other.

According to the system-on-chip semiconductor structure described in one embodiment of the present invention, an operation voltage of the aforementioned low voltage device is about 0˜3.3 voltage.

According to the system-on-chip semiconductor structure described in one embodiment of the present invention, an operation voltage of the aforementioned middle voltage device is about 3.3˜20 voltage.

According to the system-on-chip semiconductor structure described in one embodiment of the present invention, an operation voltage of the aforementioned high voltage device is larger than 20 voltages.

According to the system-on-chip semiconductor structure described in one embodiment of the present invention, the aforementioned isolation structures include shallow trench isolations.

The present invention further provides a system-on-chip semiconductor structure. The system-on-chip semiconductor structure comprises a substrate, a low voltage device, a middle voltage device, a first high voltage device and a plurality of isolation structures. The substrate has a first conductive type, wherein the substrate comprises a low voltage circuit region, a high voltage circuit region and a first well region with the first conductive type. The low voltage device is located on the low circuit region of the substrate. The middle voltage device is located on the low circuit region of the substrate. The first high voltage device having a second conductive type is located on the high circuit region of the substrate, wherein the high voltage device comprises s first metal-oxide semiconductor transistor with the second conductive type, a deep isolation well region with the second conductive type and an isolation well region with the first conductive type. The first metal-oxide semiconductor transistor is located on the substrate. The deep isolation well region is located in a portion of the substrate under the first metal-oxide semiconductor transistor and the isolation well region is located under the first metal-oxide semiconductor transistor and in the deep isolation well region. The isolation structures are located in the substrate for isolating the low voltage circuit, the middle voltage circuit and the first high voltage device from each other.

According to the system-on-chip semiconductor structure described in one embodiment of the present invention, the depth of the aforementioned deep isolation well region is larger than the depth of the aforementioned first well region and larger than the depth of the aforementioned isolation well region.

According to the system-on-chip semiconductor structure described in one embodiment of the present invention, the depth of the aforementioned isolation well region is as same as the depth of the aforementioned first well region.

According to the system-on-chip semiconductor structure described in one embodiment of the present invention, the system-on-chip semiconductor structure further comprises a second high voltage device with the second conductive type located on the high voltage circuit of the substrate.

According to the system-on-chip semiconductor structure described in one embodiment of the present invention, the aforementioned second high voltage device includes a second metal-oxide semiconductor transistor with the second conductive type located on the aforementioned first well region.

According to the system-on-chip semiconductor structure described in one embodiment of the present invention, an operation voltage of the second high voltage device is larger than 20 voltages.

According to the system-on-chip semiconductor structure described in one embodiment of the present invention, the system-on-chip semiconductor structure further comprises a third high voltage device with the first conductive type located on the substrate.

According to the system-on-chip semiconductor structure described in one embodiment of the present invention, the third high voltage device comprises a third metal-oxide semiconductor transistor with the first conductive type and a second well region with the second conductive type. The third metal-oxide semiconductor transistor is located on the substrate and the second well region is located under the third metal-oxide semiconductor transistor in the substrate.

According to the system-on-chip semiconductor structure described in one embodiment of the present invention, the depth of the second well region is smaller than the depth of the deep isolation region.

According to the system-on-chip semiconductor structure described in one embodiment of the present invention, the depth of the second well region is as same as the depth of the first well region.

According to the system-on-chip semiconductor structure described in one embodiment of the present invention, an operation voltage of the third high voltage device is larger than 20 voltages.

According to the system-on-chip semiconductor structure described in one embodiment of the present invention, the low voltage device and the middle voltage device respectively comprise a complementary metal-oxide semiconductor transistor and a deep well region with the second conductive type. The complementary metal-oxide semiconductor transistor is located on the substrate and the deep well region is located in the substrate under the complementary metal-oxide semiconductor transistor.

According to the system-on-chip semiconductor structure described in one embodiment of the present invention, the depth of the deep well region is smaller than the deep isolation well region.

According to the system-on-chip semiconductor structure described in one embodiment of the present invention, the depth of the deep well region is as same as the depth of the first well region.

According to the system-on-chip semiconductor structure described in one embodiment of the present invention, an operation voltage of the low voltage device is about 0˜3.3 voltage.

According to the system-on-chip semiconductor structure described in one embodiment of the present invention, an operation voltage of the middle voltage device is about 3.3˜20 voltage.

According to the system-on-chip semiconductor structure described in one embodiment of the present invention, an operation voltage of the first high voltage device is larger than 20 voltages.

According to the system-on-chip semiconductor structure described in one embodiment of the present invention, the isolation structures include shallow trench isolations.

The present invention also provides a method for manufacturing a system-on-chip semiconductor structure. The method comprises steps of providing a substrate having a first conductive type, wherein the substrate possesses a low voltage circuit region and a high voltage circuit region. A plurality of isolation structures are formed in the substrate. A first well region having the first conductive type is formed in the substrate. A plurality of high voltage devices are formed on a portion of the substrate between the isolation structures in the high voltage circuit region. A low voltage device and a middle voltage device are formed on a portion of the substrate between the isolation structures in the low voltage circuit region.

According to the system-on-chip semiconductor structure described in one embodiment of the present invention, the high voltage devices include a first high voltage device with a second conductive type, a second high voltage device with the second conductive type and a third high voltage device with the first conductive type.

According to the system-on-chip semiconductor structure described in one embodiment of the present invention, the method for forming the first high voltage device comprises steps of forming a deep isolation well region having the second conductive type in the substrate, wherein a portion of the first well region is located in the deep isolation well region. Then, a first metal-oxide semiconductor transistor having the second conductive type is formed on the substrate above the deep isolation well region.

According to the system-on-chip semiconductor structure described in one embodiment of the present invention, the depth of the deep isolation well region is larger than the depth of the first well region.

According to the system-on-chip semiconductor structure described in one embodiment of the present invention, the method for forming the second high voltage device comprises a step of forming a second metal-oxide semiconductor transistor having the second conductive type on the substrate above the first well region.

According to the system-on-chip semiconductor structure described in one embodiment of the present invention, the method for forming the third high voltage device comprises steps of forming a second well region having the second conductive type in the substrate and then forming a third metal-oxide semiconductor transistor having the first conductive type on the substrate above the second well region.

According to the system-on-chip semiconductor structure described in one embodiment of the present invention, the depth of the second well region is as same as the depth of the first well region.

According to the system-on-chip semiconductor structure described in one embodiment of the present invention, the method for forming the low voltage device and the middle voltage device comprises steps of forming a deep well region having the second conductive type in the substrate and then forming a complementary metal-oxide semiconductor transistor on the substrate above the deep well region.

According to the system-on-chip semiconductor structure described in one embodiment of the present invention, the depth of the deep well region is as same as the depth of the first well region.

According to the system-on-chip semiconductor structure described in one embodiment of the present invention, an operation voltage of the low voltage device is about 0˜3.3 voltage.

According to the system-on-chip semiconductor structure described in one embodiment of the present invention, an operation voltage of the middle voltage device is about 3.3˜20 voltage.

According to the system-on-chip semiconductor structure described in one embodiment of the present invention, an operation voltage of the high voltage device is larger than 20 voltages.

According to the system-on-chip semiconductor structure described in one embodiment of the present invention, the isolation structures include shallow trench isolations.

In the present invention, the high voltage devices, the middle voltage device and the low voltage device are all arranged in the same chip so that the product size is decreased and the number of the semiconductor devices arranged in a single product can be increased. Hence, the product can possess multiple functions. Furthermore, in the high voltage circuit region of the system-on-chip semiconductor structure, the deep isolation well region with the conductive type different from that of the substrate is used to isolate the high voltage devices from the substrate. Therefore, the high voltage devices can be prevented from being interfered from the substrate. In addition, in the low voltage circuit region of the system-on-chip semiconductor structure, the deep well region with the conductive type different from that of the substrate is used to isolate the low voltage device and the middle voltage device from the high voltage devices. Hence, the low voltage device and the middle voltage can be prevented from being interfered by the intensive electric field generated by the high voltage devices.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is cross-sectional view showing a system-on-chip semiconductor structure according to the preferred embodiment of the present invention.

FIGS. 2A through 2D are cross-sectional views illustrating a method for forming a system-on-chip semiconductor structure according to one embodiment of the present invention.

### DESCRIPTION OF THE PREFERRED EMBODIMENTS

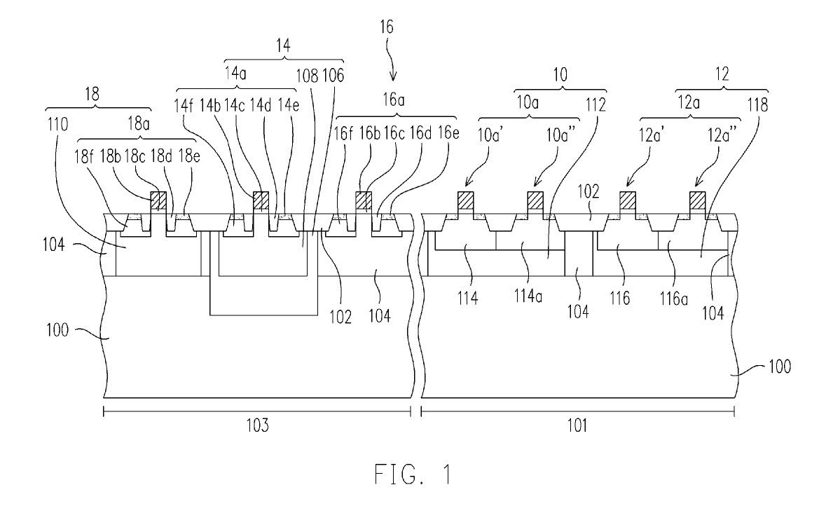

FIG. 1 is used to describe a system-on-chip semiconductor structure having a low voltage device, a middle voltage device and high voltage devices located on the same chip.

FIG. 1 is cross-sectional view showing a system-on-chip semiconductor structure according to the preferred embodiment of the present invention. As shown in FIG. 1, the system-on-chip semiconductor structure comprises a substrate 100 having a first conductive type, a low voltage device 10, a middle voltage device 12, high voltage devices 14 and 16 having a second conductive type, a high voltage device 18 having the first conductive type and an isolation structure 102. The substrate 100 has a medium-and-low voltage circuit region 101 and a high voltage circuit region 103. The substrate 100 further comprises a well region 104 having the first conductive type. The depth of the well region 104 is about 3 micron meter. The low voltage device 10 and the middle voltage device 12 are located on the substrate 100 in the medium-and-low voltage circuit region 101. The high voltage devices 14, 16 and 18 are located on the substrate 100 in the high voltage circuit region 103. The isolation structure 102 is located in the substrate 100 and isolates the low voltage device 10, the middle voltage device 12, the high voltage devices 14, 16 and 18 from each other. The isolation structures 102 can be, for example but not limited to, a shallow trench isolation.

As shown in FIG. 1, the high voltage device 14 can be, for example but not limited to, a field drift metal-oxide semiconductor (FDMOS) and the operation voltage of the high voltage device 14 can be, for example, larger than 20 voltage. The high voltage device 14 includes a metal-oxide semiconductor (MOS) transistor 14a having the second conductive type, a deep isolation well region 106 having the second conductive type and an isolation well region 108 having the first conductive type, wherein the MOS transistor 14a has a gate electrode 14b, a gate dielectric layer 14c, an isolation structure 14d, a source/drain region 14e and a drift region 14f. The MOS transistor 14a is located on the substrate 100. The thickness of the gate dielectric layer 14b is about 500˜1000 angstroms. The isolation structure 14d can be, for example but not limited to, shallow trench isolation. The isolation structure 14d and the drift region 14f are used to alleviate hot electron effect so as to increase the breakdown voltage of the source/drain region 14e. The deep isolation well region 106 is located in the substrate 100 under the MOS transistor 14a. The isolation well region 108 is located in the substrate 100 under the MOS transistor 14a and in the deep isolation well region 106 so that the isolation well region 108 is isolated from the well region 104 which has the conductive type as same as that of the isolation well region 108. The depth of the isolation well region 108 is as same as that of the well region 104 and the depth of the deep isolation well region 106 is larger than that of the well region 104 and larger than that of the isolation well region 108. In the present embodiment, the depth of the well region 104 and the depth of the isolation well region 108 are about 3 micron meter respectively.

It should be noticed that, in the present embodiment, the deep isolation well region 108 having the conductive type different from that of the substrate is used to isolate the high voltage device 14 from the substrate 100 so as to prevent the high voltage device 14 from being interfered by the substrate 100. Also, the deep isolation well region 108 can be used as a level shift. Furthermore, the deep isolation well region 106 isolates the high voltage device 14 from other devices in the high voltage circuit region 103 so that the high voltage device 14 can be independently operated.

As shown in FIG. 1, the high voltage device 16 can be, for example but not limited to, a FDMOS and the operation voltage of the high voltage device 16 can be, for example, larger than 20 voltage. The high voltage device 16 can be, for example, a MOS transistor 16a having the second conductive type. The MOS transistor 16a comprises a gate electrode 16b, a gate dielectric layer 16c, an isolation structure 16d, a source/drain region 16e and a drift region 16f. The MOS transistor 16a is located on the well region 104. The thickness of the gate dielectric layer 16b is about 500˜1000 angstroms. The isolation structure 16d can be, for example but not limited to, a shallow trench isolation. The isolation structure 16d and the drift region 16f are used to alleviate hot electron effect so as to increase the breakdown voltage of the source/drain region 16e.

As shown in FIG. 1, the high voltage device 18 can be, for example but not limited to, a FDMOS and the operation voltage of each of the high voltage device 18 can be, for example, larger than 20 voltage. The high voltage device 18 comprises a MOS transistor 18a having the first conductive type and a well region 110 having the second conductive type. The MOS transistor 18a comprises a gate electrode 18b, a gate dielectric layer 18c, an isolation structure 18d, a source/drain region 18e and a drift region 18f. The MOS transistor 18a is located on the substrate 100. The thickness of the gate dielectric layer 18b is about 500˜1000 angstroms. The isolation structure 18d can be, for example but not limited to, a shallow trench isolation. Similarly, the isolation structure 18d and the drift region 18f are used to alleviate hot electron effect so as to increase the breakdown voltage of the source/drain region 18e. The depth of the well region 110 is as same as that of the well region 104 and the depth of each of the well region 110 and the well region 104 is about 3 micron meter.

It should be noticed that all the high voltage devices 14,16 and 18 can be FDMOS so that the high voltage devices can be operated over 40 voltage without being damaged. Furthermore, the high voltage devices can be used for processing the signals of the gate driver. Additionally, in the embodiment, the positions of the high voltage devices 14, 16 and 18 in the high voltage circuit region 103 can be varied with the demands of the products and are not limited to the configuration shown in the present embodiment.

As shown in FIG. 1, the low voltage device 10 comprises a complementary MOS transistor 10a and a deep well region 112 having the second conductive type. The operation voltage of the low voltage device 10 is about 0˜3.3 voltage. The complementary MOS transistor 10a is located on the substrate 100. The complementary MOS transistor 10a is composed of a MOS transistor 110a′ having the second conductive type in a well region 114 having the first conductive type and a MOS transistor 10″ having the first conductive type in a well region 114a having the second conductive type. The deep well region 112 is located in the substrate 100 under the complementary MOS transistor 10a. The depth of the deep well region 112 can be, for example, as same as that of the well region 104 and is smaller than that of the deep isolation well region 106. In the present embodiment, the depth of the deep well region 112 is about 3 micron meter. Moreover, the middle voltage device 12 comprises a complementary MOS transistor 12a and a deep well region 116 having the second conductive type. The operation voltage of the middle voltage device 12 is about 3.3˜20 voltage. Similar to the low voltage device 10, the complementary MOS transistor 12a is located on the substrate 100. The complementary MOS transistor 12a is composed of a MOS transistor 12a′ having the second conductive type in a well region 116 having the first conductive type and a MOS transistor 12″ having the first conductive type in a well region 116a having the second conductive type. The deep well region 118 is located in the substrate 100 under the complementary MOS transistor 12a.

It should be noticed that the deep well regions 112 and 118 are located in the substrate 100 under the MOS transistors 10a and 12a respectively. Therefore, the low voltage device 10 and the middle voltage device 12 are individually independent and the low voltage device 10 and the middle voltage device 12 are free from the interference of the high voltage device. Moreover, in the present embodiment, the low voltage device 10 can be used to operate the logic operation in the memory under 2.5 voltage and the middle voltage device 12 can be used to process the signals of the source driver.

It should be noticed that, in the present invention, the high voltage devices, the low voltage device and the middle voltage device are located at the same chip so as to decrease the space occupied by the chip and to decrease the size of the product. Therefore, the configuration of the high voltage devices in the high voltage circuit region can be adjusted with the demands of the products and is not limited to the configuration shown in the present embodiment.

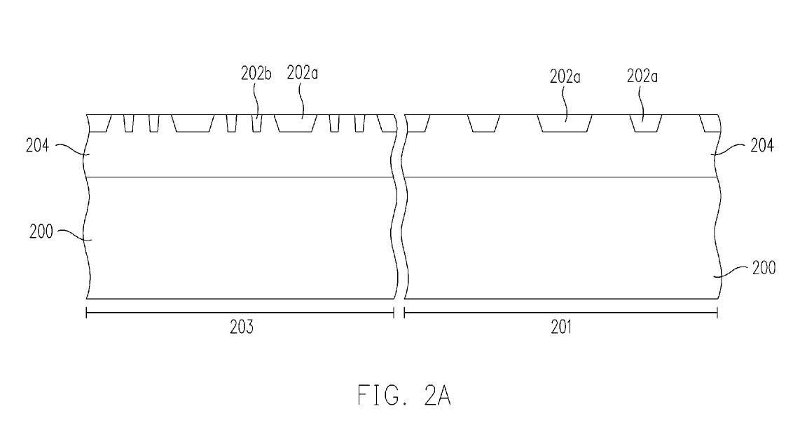

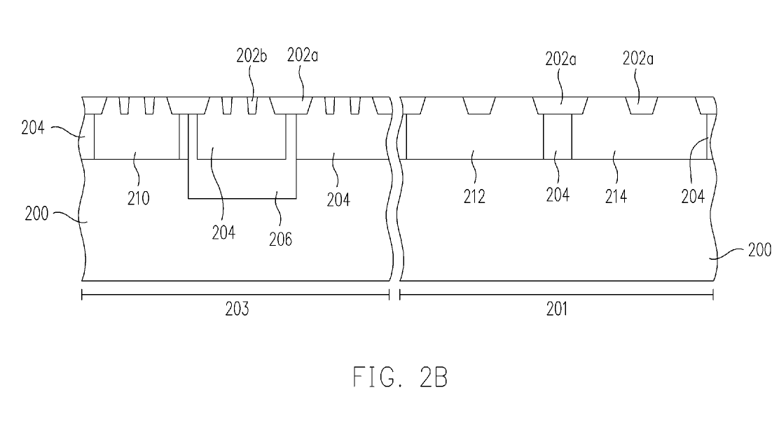

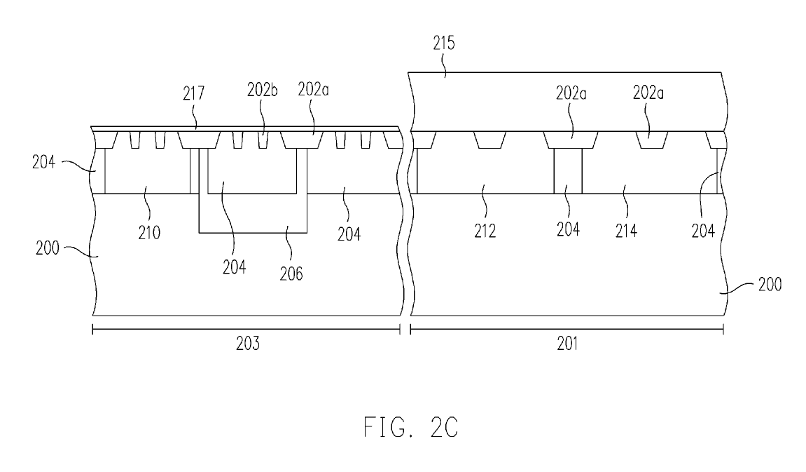

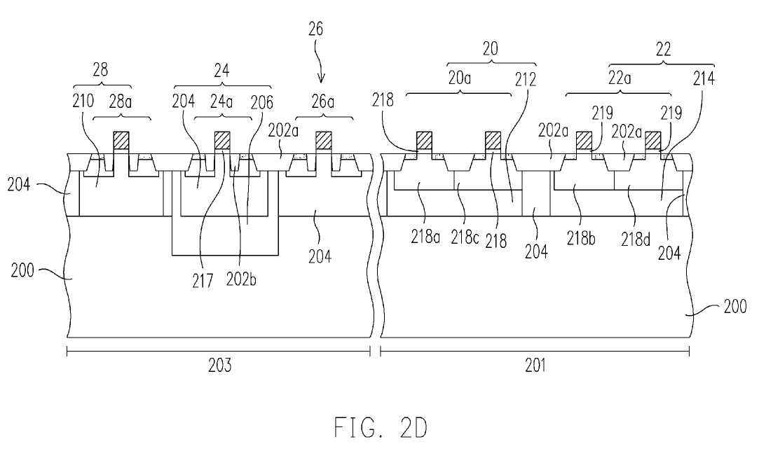

FIGS. 2A through 2D are cross-sectional views illustrating a method for forming a system-on-chip semiconductor structure according to one embodiment of the present invention.

As shown in FIG. 2A, a substrate 200 having the first conductive type is provided, wherein the substrate 200 has a low voltage circuit region 201 and a high voltage circuit region 203. Then, several isolation structures 202a and 202b are formed in the substrate 200. The method for forming the isolation structures 202a and 202b comprises a step of performing a shallow trench isolation process. The material of the isolation structures 202a and 202b can be, for example but not limited to, silicon oxide. A well region 204 having the first conductive type in the substrate 200. The method for forming the well region 204 comprises a step of performing an ion implantation process to implant dopants with the first conductive type into the substrate 200.

As shown in FIG. 2B, a deep isolation well region 206 having the second conductive type is formed in the substrate 200 between the isolation structures 202a. The method for forming the deep isolation well region 206 comprises steps of performing an ion implantation process to implant dopants with second conductive type into the substrate 200, and then performing a drive-in process to form the deep isolation well region 206 with relatively large depth around the well region 204. In this embodiment, the depth of the well region 204 is about 3 micron meter and the depth of the deep isolation well region 206 is about 6 micron meter. It should be noticed that the well region 204 located in the deep isolation well region 206 is the isolation well region 108 shown in FIG. 1. Thereafter, a well region 210 having the second conductive type, deep well regions 212 and 214 with the second conductive type are formed in the substrate 200. Further, the depth of each of the well region 210 and the deep well regions 212 and 214 can be, for example, as same as that of the well region 204 and smaller than the deep isolation well region 206. The method for forming the well region 210, the deep well regions 212 and 214 comprises a step of performing an ion implantation process. In this embodiment, the depth of each of the well region 210 and the deep well regions 212 and 214 is about 3 micron meter.

As shown in FIG. 2C, a dielectric layer 217 is formed on the substrate 200 in the high voltage circuit region 203 so that the dielectric layer 217 can be the gate dielectric layer of the later formed high voltage device. The material of the dielectric layer 217 can be, for example but not limited to, silicon oxide and the thickness of the dielectric layer 217 is about 500˜1000 angstroms. The method for forming the dielectric layer 217 comprises steps of forming a hard mask layer 215 on the substrate 200 in the low voltage circuit region 201 and then performing a thermal oxidation process to form the dielectric layer 217 on the substrate 200 in the high voltage circuit region 203. The material of the hard mask layer 215 can be, for example but not limited to, silicon nitride and the thickness of the hard mask layer 215 is about 300 angstroms. By performing the thermal oxidation process, the periphery of the isolation structures 202 can be prevented from being too thin.

As shown in FIG. 2D, the hard mask layer 215 is removed. Then, a dielectric layer 218 and a dielectric layer 219 are formed on the substrate 200 over the deep well region 212 and the deep well region 214 respectively so that the dielectric layer 218 can be the gate dielectric layer of the later formed low voltage device and the dielectric layer 219 can be the gate dielectric layer of the later formed middle voltage device. The thickness of the dielectric layer 218 is about 40˜70 angstroms. The thickness of the dielectric layer 219 is about 80˜150 angstroms. Then, well regions 218a and 218b having the first conductive type and the well regions 218c and 218d having the second conductive type are formed in the substrate 200 by performing an ion implantation process and then a serial steps of well known semiconductor manufacturing processes is performed to form high voltage devices 24, 26 and 28 in the high voltage circuit region 203 and to form a low voltage device 20 and a middle voltage device 22 in the low voltage circuit region 201. In this embodiment, the operation voltage of the low voltage device 20 is about 0˜3.3 voltage. The operation voltage of the middle voltage device 22 is about 3.3˜20 voltage. The operation voltage of each of the high voltage devices 24, 26 and 28 can be, for example, larger than 20 voltage.

In this embodiment, the method for forming the high voltage device 24 comprises a step of forming a MOS transistor 24a with the second conductive type on the substrate 200 after the deep isolation well region 206 is formed around the well region 204. The method for forming the high voltage device 26 comprises a step of forming a MOS transistor 26a with the second conductive type on the substrate 200 over the well region 204. The method for forming the high voltage device 28 comprises a step of forming a MOS transistor 28a with the first conductive type on the substrate 200 over the well region 210 after the well region 210 is formed in the substrate 200. The method for forming the low voltage device 20 and the middle voltage device 22 can, for example, comprise a step forming a complementary MOS transistors 20a and 22a on the substrate over the deep well region 212 after the deep well region 212 is formed in the substrate 200. Notably, the depth of the deep isolation well region 206 in the substrate 200 is larger than the depth of each of the well regions 204 and 210 and the deep well regions 212 and 214.

Altogether, in the present invention, the high voltage devices, the middle voltage device and the low voltage device are all arranged in the same system on chip so that the number of the chips in a single product can be decreased and the space occupied by the chips in a single product can be decreased as well. Accordingly, the size of the product is decreased and the number of the semiconductor devices equipped in a single product is increased. Hence, the product can possess multiple functions. Furthermore, in the high voltage circuit region of the system-on-chip semiconductor structure of the present invention, the deep isolation well region with the conductive type different from that of the substrate is used to isolate the high voltage devices from the substrate. Therefore, the high voltage devices can be prevented from being interfered from the substrate. In addition, in the low voltage circuit region of the system-on-chip semiconductor structure, the deep well region with the conductive type different from that of the substrate is used to isolate the low voltage device and the middle voltage device from the high voltage devices. Hence, the low voltage device and the middle voltage can be prevented from being interfered by the intensive electric field generated by the high voltage devices.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A system-on-chip semiconductor structure, comprising:
a substrate having a low voltage circuit region and a high voltage circuit region;
a low voltage device located on the low voltage circuit region of the substrate;
a middle voltage device located on the low voltage circuit region of the substrate;
at least one high voltage device located on the high voltage circuit region of the substrate; and
a plurality of isolation structures located in the substrate for isolating the low voltage device, the middle voltage device and the high voltage device from each other.

2. The system-on-chip semiconductor structure of claim 1, wherein an operation voltage of the low voltage device is about 0˜3.3 voltage.

3. The system-on-chip semiconductor structure of claim 1, wherein an operation voltage of the middle voltage device is about 3.3˜20 voltage.

4. The system-on-chip semiconductor structure of claim 1, wherein an operation voltage of the high voltage device is larger than 20 voltage.

5. The system-on-chip semiconductor structure of claim 1, wherein the isolation structures include shallow trench isolations.

6. A system-on-chip semiconductor structure, comprising:
a substrate having a first conductive type, wherein the substrate comprises a low voltage circuit region, a high voltage circuit region and a first well region with the first conductive type;
a low voltage device located on the low circuit region of the substrate;
a middle voltage device located on the low circuit region of the substrate;
a first high voltage device with a second conductive type located on the high circuit region of the substrate, wherein the high voltage device comprises:
a first metal-oxide semiconductor transistor with the second conductive type located on the substrate;
a deep isolation well region with the second conductive type located in a portion of the substrate under the first metal-oxide semiconductor transistor; and
an isolation well region with the first conductive type located under the first metal-oxide semiconductor transistor and in the deep isolation well region; and
a plurality of isolation structures located in the substrate for isolating the low voltage circuit, the middle voltage circuit and the first high voltage device from each other.

7. The system-on-chip semiconductor structure of claim 6, wherein the depth of the deep isolation well region is larger than the depth of the first well region and larger than the depth of the isolation well region.

8. The system-on-chip semiconductor structure of claim 6, wherein the depth of the isolation well region is as same as the depth of the first well region.

9. The system-on-chip semiconductor structure of claim 6 further comprising a second high voltage device with the second conductive type located on the high voltage circuit of the substrate.

10. The system-on-chip semiconductor structure of claim 9, wherein the second high voltage device includes a second metal-oxide semiconductor transistor with the second conductive type located on the first well region.

11. The system-on-chip semiconductor structure of claim 10, wherein an operation voltage of the second high voltage device is larger than 20 voltage.

12. The system-on-chip semiconductor structure of claim 6 further comprising a third high voltage device with the first conductive type located on the substrate.

13. The system-on-chip semiconductor structure of claim 12, wherein the third high voltage device comprises:
a third metal-oxide semiconductor transistor with the first conductive type located on the substrate; and
a second well region with the second conductive type located under the third metal-oxide semiconductor transistor in the substrate.

14. The system-on-chip semiconductor structure of claim 12, wherein the depth of the second well region is smaller than the depth of the deep isolation region.

15. The system-on-chip semiconductor structure of claim 12, wherein the depth of the second well region is as same as the depth of the first well region.

16. The system-on-chip semiconductor structure of claim 12, wherein an operation voltage of the third high voltage device is larger than 20 voltage.

17. The system-on-chip semiconductor structure of claim 6, wherein the low voltage device and the middle voltage device respectively comprise:
a complementary metal-oxide semiconductor transistor located on the substrate; and
a deep well region with the second conductive type located in the substrate under the complementary metal-oxide semiconductor transistor.

18. The system-on-chip semiconductor structure of claim 17, wherein the depth of the deep well region is smaller than the deep isolation well region.

19. The system-on-chip semiconductor structure of claim 17, wherein the depth of the deep well region is as same as the depth of the first well region.

20. The system-on-chip semiconductor structure of claim 6, wherein an operation voltage of the low voltage device is about 0˜3.3 voltage.

21. The system-on-chip semiconductor structure of claim 6, wherein an operation voltage of the middle voltage device is about 3.3˜20 voltage.

22. The system-on-chip semiconductor structure of claim 6, wherein an operation voltage of the first high voltage device is larger than 20 voltage.

23. The system-on-chip semiconductor structure of claim 6, wherein the isolation structures include shallow trench isolations.

24. A method for manufacturing a system-on-chip semiconductor structure, comprising:
providing a substrate having a first conductive type, wherein the substrate possesses a low voltage circuit region and a high voltage circuit region;
forming a plurality of isolation structures in the substrate;
forming a first well region having the first conductive type in the substrate;
forming a plurality of high voltage devices on a portion of the substrate between the isolation structures in the high voltage circuit region; and
forming a low voltage device and a middle voltage device on a portion of the substrate between the isolation structures in the low voltage circuit region.

25. The method of claim 24, wherein the high voltage devices include a first high voltage device with a second conductive type, a second high voltage device with the second conductive type and a third high voltage device with the first conductive type.

26. The method of claim 25, wherein the method for forming the first high voltage device comprises:
forming a deep isolation well region having the second conductive type in the substrate, wherein a portion of the first well region is located in the deep isolation well region; and
forming a first metal-oxide semiconductor transistor having the second conductive type on the substrate above the deep isolation well region.

27. The method of claim 26, wherein the depth of the deep isolation well region is larger than the depth of the first well region.

28. The method of claim 25, wherein the method for forming the second high voltage device comprises a step of forming a second metal-oxide semiconductor transistor having the second conductive type on the substrate above the first well region.

29. The method of claim 25, wherein the method for forming the third high voltage device comprises:
forming a second well region having the second conductive type in the substrate; and
forming a third metal-oxide semiconductor transistor having the first conductive type on the substrate above the second well region.

30. The method of claim 29, wherein the depth of the second well region is as same as the depth of the first well region.

31. The method of claim 24, wherein the method for forming the low voltage device and the middle voltage device comprises:
forming a deep well region having the second conductive type in the substrate; and
forming a complementary metal-oxide semiconductor transistor on the substrate above the deep well region.

32. The method of claim 31, wherein the depth of the deep well region is as same as the depth of the first well region.

33. The method of claim 24, wherein an operation voltage of the low voltage device is about 0˜3.3 voltage.

34. The method of claim 24, wherein an operation voltage of the middle voltage device is about 3.3˜20 voltage.

35. The method of claim 24, wherein an operation voltage of the high voltage device is larger than 20 voltages.

36. The method of claim 24, wherein the isolation structures include shallow trench isolations.
